(19) United States
(12) Patent Application Publication
(10) Pub. No.: US 2007/0045227 A1
(43) Pub. Date: Mar. 1, 2007

(54) METHOD OF STRIPPING PHOTORESIST

(76) Inventors: Chih-Ning Wu, Hsinchu (TW); Hsin Tai, Taipei City (TW); Yi-Yiing Chiang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,156

(22) Filed: Aug. 31, 2005

(51) Int. Cl. C23F 1/00; H01L 21/302; B44C 1/22; C03C 25/68

(52) U.S. Cl. 216/41; 438/706; 438/725; 216/58

(57) ABSTRACT

A method of stripping photoresist is provided. First, a first dielectric layer including a plurality of contact structures is provided. Then, a barrier layer is formed over the first dielectric layer. Thereafter, a second dielectric layer is formed over the barrier layer. Next, a patterned photoresist layer is formed over the second dielectric layer. Then, the patterned photoresist layer is used as a mask layer for patterning the second dielectric layer and the barrier layer to expose a portion of the contact structures. Furthermore, the patterned photoresist layer is removed by using an oxygen-free reducing gas. Since the reducing gas does not contain oxygen, the process can prevent oxide from forming on the contact structures, thereby reducing resistance of the contact structures.

### BACKGROUND OF THE INVENTION

1. Field of the Invention

The present invention relates to a semiconductor manufacturing process, and more particularly to a method of stripping photoresist.

2. Description of the Related Art

The conventional method of stripping photoresist may be classified into a wet photoresist stripping method and a dry photoresist stripping method. In the wet photoresist stripping method, the patterned photoresist layer is removed by using a photoresist stripping solution. However, the photoresist stripping solution reacts with metal conductors and substrate exposed by contact windows or trenches, thus eroding or destroying profiles of these contact windows and trenches, or forming metal oxide, which would increase resistance in areas near these contact windows. Because the wet photoresist stripping method has such serious disadvantages, the dry photoresist stripping method becomes the main approach to remove photoresist.

The dry photoresist stripping method may be classified into two approaches. In one method, plasma etching process is adopted for stripping the photoresist, wherein oxygen plasma is generally used. In the other method, ashing process is adopted for striping the photoresist by using oxygen under high temperature. However, the chemical reactive metal conductors may be oxidized by the oxygen or oxygen ions used in the dry photoresist stripping method. That is, metal oxide will be formed over the metal conductors, which will increase the resistance of the metal conductors, and affect electrical performance of devices. Though the conventional method uses an ammonium-based solution for cleaning the surface of the metal conductors, the metal oxide on the surface cannot be removed effectively.

### SUMMARY OF THE INVENTION

Accordingly, the present invention is directed to a method of stripping photoresist to reduce resistance of metal conductors.

The present invention provides a method of stripping photoresist. In the method, a first dielectric layer is formed, and the first dielectric layer may comprise a plurality of contact structures. Then, a barrier layer is formed over the first dielectric layer. Next, a second dielectric layer is formed over the barrier layer. Then, a patterned photoresist layer is formed over the second dielectric layer. Next, the second dielectric layer and the barrier layer are patterned to expose a portion of the contact structures by using the patterned photoresist layer as a mask. Thereafter, the patterned photoresist layer is removed by using a reducing gas. It should be noted that, the reducing gas may comprise an oxygen-free gas.

According to an embodiment of the present invention, in the method of stripping photoresist above, the method further comprises forming an anti-reflection layer after forming the second dielectric layer and before forming the patterned photoresist layer.

According to an embodiment of the present invention, in the method of stripping photoresist above, the step of removing the patterned photoresist layer by using the reducing gas and the step of patterning the second dielectric layer and the barrier layer are performed in-situ.

According to an embodiment of the present invention, in the method of stripping photoresist above, the step of removing the patterned photoresist layer by using the reducing gas comprises a plasma etching process, for example.

According to an embodiment of the present invention, in the method of stripping photoresist above, the reducing gas comprises, for example, an gas mixture containing inert gas and hydrogen or gas mixture containing nitrogen and hydrogen.

According to an embodiment of the present invention, in the method of stripping photoresist above, the gas mixture containing inert gas and hydrogen comprises, for example, helium/hydrogen (He/H₂), argon/hydrogen (Ar/H₂), or xenon/hydrogen (Xe/H₂).

According to an embodiment of the present invention, in the method of stripping photoresist above, the reducing gas is ionized during the plasma etching process.

According to an embodiment of the present invention, in the method of stripping photoresist above, the step of removing the patterned photoresist layer by using the reducing gas and the step of patterning the second dielectric layer and the barrier layer are performed ex-situ.

According to an embodiment of the present invention, in the method of stripping photoresist above, the step of removing the patterned photoresist layer by using the reducing gas comprises an ashing process, for example.

According to an embodiment of the present invention, in the method of stripping photoresist above, the reducing gas comprises, for example, an gas mixture containing inert gas and hydrogen.

According to an embodiment of the present invention, in the method of stripping photoresist above, the gas mixture containing inert gas and hydrogen comprises, for example, helium/hydrogen (He/H₂) or nitrogen/ hydrogen (N₂/H₂).

According to an embodiment of the present invention, in the method of stripping photoresist above, the reducing gas may be radical during the ashing process.

According to an embodiment of the present invention, in the method of stripping photoresist above, a material of the contact structures comprises, for example, nickel silicide or an alloy containing nickel silicide. In addition, the alloy containing nickel silicide comprises, for example, platinum or palladium.

According to an embodiment of the present invention, in the method of stripping photoresist above, a material of the barrier layer comprises silicon nitride, for example.

According to an embodiment of the present invention, in the method of stripping photoresist above, the method further comprises performing a wet clean process after the step of removing the photoresist layer by using the reducing gas.

According to an embodiment of the present invention, in the method of stripping photoresist above, a solvent adopted for the wet clean process may comprise an ammonium hydroxide-hydrogen peroxide water (APM) solution, or a fluorine based solution. In addition, a ratio of ammonium hydroxide, hydrogen peroxide and water of the APM solution is 1:1:100.

Accordingly, in the method of stripping photoresist according to the present invention, the reducing gas is oxygen-free so that the formation of metal oxide can be effectively avoided, and the resistance of metal conductors can be reduced. In addition, the method of stripping photoresist comprises a wet clean process after the dry photoresist stripping step. The wet clean process can effectively remove the patterned photoresist layer to avoid unexpected reaction of the residual photoresist during the subsequent process. Therefore, the device performance can thus be improved. Furthermore, in the method of stripping photoresist according to the present invention, the step of removing the patterned photoresist layer using the reducing gas and the step of removing the second dielectric layer and the barrier layer may be performed in-situ. Thus, the manufacturing flow is simplified.

The above and other features of the present invention will be better understood from the following detailed description of the preferred embodiments of the invention that is provided in communication with the accompanying drawings.

### BRIEF DESCRIPTION OF THE DRAWINGS

FIGS. 1A-1D are schematic cross-sectional views illustrating a process flow of forming contact windows according to an embodiment of the present invention.

### DESCRIPTION OF SOME EMBODIMENTS

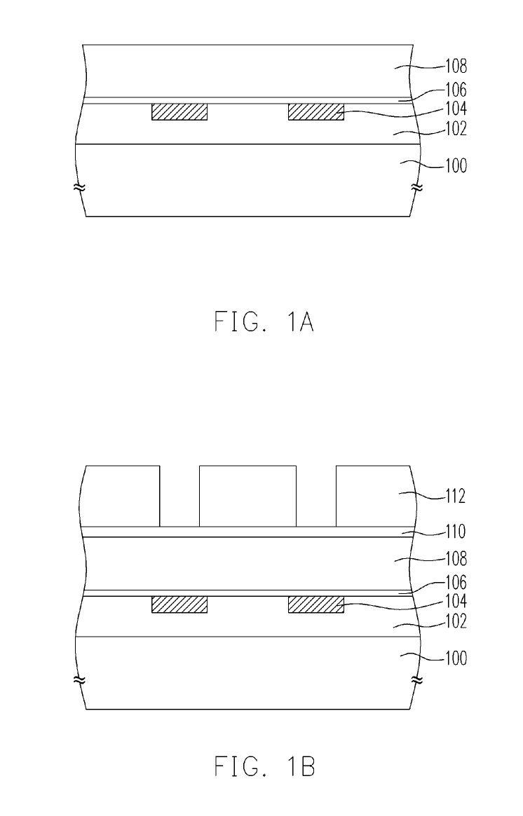

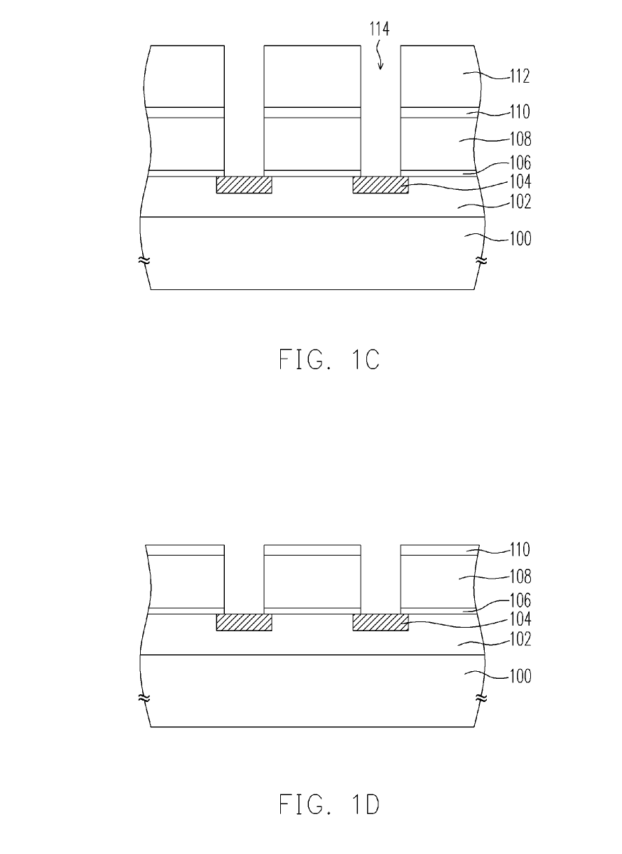

FIGS. 1A-1D are schematic cross-sectional views illustrating a process flow of forming contact windows according to an embodiment of the present invention. Referring to FIG. 1A, a dielectric layer 102 is formed over a semiconductor substrate 100. The dielectric layer 102 may comprise a plurality of contact structures 104. In one embodiment of the present invention, the material of the contact structures 104 can be, for example, nickel silicide or an alloy comprising nickel silicide. The alloy containing nickel silicide comprises, for example, platinum or palladium.

Referring to FIG. 1A, a barrier layer 106 is formed over the dielectric layer 102. In one embodiment of the present invention, the material of the barrier layer 106 can be, for example, silicon nitride. In addition, the barrier layer 106 can be formed by a chemical vapor deposition (CVD) method, for example. A dielectric layer 108 is then formed over the barrier layer 106. The material of the barrier layer 108 can be, for example, silicon nitride. Moreover, the barrier layer 108 can be formed by a CVD method, for example.

Referring to FIG. 1B, a patterned photoresist layer 112 is formed over the dielectric layer 108. The method of forming the patterned photoresist layer 112 may comprise the following steps. First, a photoresist layer (not shown) may be formed over the dielectric layer 108. Then, a photolithographic process is performed on the photoresist layer to form the patterned photoresist layer 112. In another embodiment of the present invention, after the step of forming the dielectric layer 108 and before the step of forming the patterned photoresist layer 112, an anti-reflection layer 110 as shown in FIG. 1B may be formed. The material of the anti-reflection layer 110 can be, for example, silicon oxynitride, and the anti-reflection layer 110 can be formed by a CVD method, for example.

Referring to FIG. 1C, the anti-reflection layer 110, the dielectric layer 108 and the barrier layer 106 are sequentially patterned by using the patterned photoresist layer 112 as a mask to form a plurality of contact windows 114 to expose a portion of the contact structures 104. The method of patterning the anti-reflection layer 110, the dielectric layer 108 and the barrier layer 106 may comprise sequentially etching each material layer to form the contact windows 114 corresponding to the contact structures 104. In anther embodiment, the etching process comprises, for example, an anisotropic etching process.

Referring to FIG. 1D, the reducing gas is used to remove the patterned photoresist layer 112. The reducing gas can be, for example, an oxygen-free gas to avoid forming oxide on the contact structures 104, thus the resistance of the contact structures 104 may be reduced. In another embodiment, the step of removing the patterned photoresist layer 112 by using the reducing gas and the step of patterning the anti-reflection layer 110, the dielectric layer 108 and the barrier layer 106 may be performed in-situ, for example. Accordingly, the manufacturing process can be simplified. In addition, the step of the removing the patterned photoresist layer 112 can be, for example, a plasma etching process. In the plasma etching process, the reducing gas is ionized. In addition, the reducing gas can be, for example, a gas mixture containing inert gas and hydrogen, or a gas mixture containing nitrogen and hydrogen. The gas mixture containing inert gas and hydrogen comprises, for example, helium/hydrogen (He/H₂), argon/hydrogen (Ar/H₂), or xenon/hydrogen (Xe/H₂).

In another embodiment of the present invention, the step of removing the patterned photoresist layer 112 by using the reducing gas and the step of patterning the anti-reflection layer 110, the dielectric layer 108 and the barrier layer 106 may be performed ex-situ, for example. In addition, the step of the removing the patterned photoresist layer 112 can be, for example, an ashing process. In one embodiment of the present invention, the reducing gas may be radical. The reducing gas can be, for example, a gas mixture containing inert gas and hydrogen. The gas mixture containing inert gas and hydrogen can be, for example, He/H₂ or N₂/H₂. A ratio of N₂ and H₂ may be 96%:4%., for example.

After the patterned photoresist layer 112 is removed by using the reducing gas, a wet clean process may be performed to remove the oxide (not shown) that may be formed on the contact structures 104. A solvent adopted for the wet clean process may comprise, for example, an ammonium hydroxide-hydrogen peroxide water (APM) solution, or a fluorine based solution. In addition, a ratio of ammonium hydroxide, hydrogen peroxide and water of the APM solution may be 1:1:100.

In the embodiments of the present invention, the method of stripping the photoresist described above is exemplarily applied in the process for forming the contact window opening 104, however, the present invention is not limited thereto. In other semiconductor processes, such as a process of forming trenches and a process of forming a dual damascene structure, the method of stripping photoresist may be applied thereto.

Accordingly, the present invention has at least the following advantages. First, in the present invention, the reducing gas for stripping the photoresist is oxygen-free, so that the formation of oxide material on the contact structure can be avoided and the resistance of the contact structure can be reduced. In addition, a wet clean process may be performed after the photoresist is removed by using the reducing gas. The wet clean process can effectively remove the patterned photoresist layer, thus the unexpected reaction of the residual photoresist in the subsequent process may be avoided. Accordingly, device performance can thus be enhanced. Furthermore, in the method of stripping photoresist, the step of removing the photoresist layer by using the reducing gas and the etching step can be performed in-situ. Thus, the manufacturing process can also be simplified.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A method of stripping photoresist, comprising:
forming a first dielectric layer, wherein the first dielectric layer comprises a plurality of contact structures;
forming a barrier layer over the first dielectric layer;
forming a second dielectric layer over the barrier layer;
forming a patterned photoresist layer over the second dielectric layer;
patterning the second dielectric layer and the barrier layer to expose a portion of the contact structures by using the patterned photoresist layer as a mask; and
removing the patterned photoresist layer by using a reducing gas, and the reducing gas comprising an oxygen-free gas.

2. The method of stripping photoresist of claim 1, wherein after forming the second dielectric layer and before forming the patterned photoresist layer, further comprising:
forming an anti-reflection layer.

3. The method of stripping photoresist of claim 1, wherein the step of removing the patterned photoresist layer by using the reducing gas and the step of patterning the second dielectric layer and the barrier layer are performed in-situ.

4. The method of stripping photoresist of claim 3, wherein the step of removing the patterned photoresist layer by using the reducing gas comprises a plasma etching process.

5. The method of stripping photoresist of claim 4, wherein the reducing gas comprises a gas mixture containing inert gas and hydrogen, or a gas mixture containing nitrogen and hydrogen.

6. The method of stripping photoresist of claim 4, wherein the gas mixture containing inert gas and hydrogen comprises helium/hydrogen (He/H₂), argon/hydrogen (Ar/H₂), or xenon/hydrogen (Xe/H₂).

7. The method of stripping photoresist of claim 4, wherein in the step of the plasma etching process, the reducing gas is ionized.

8. The method of stripping photoresist of claim 1, wherein the step of removing the patterned photoresist layer by using the reducing gas and the step of patterning the second dielectric layer and the barrier layer are performed ex-situ.

9. The method of stripping photoresist of claim 8, wherein the step of removing the patterned photoresist layer by using the reducing gas comprises an ashing process.

10. The method of stripping photoresist of claim 9, wherein the reducing gas comprises a gas mixture containing inert gas and hydrogen.

11. The method of stripping photoresist of claim 10, wherein the gas mixture containing inert gas and hydrogen comprises helium/hydrogen (He/H₂) or nitrogen/hydrogen (N₂/H₂).

12. The method of stripping photoresist of claim 9, wherein in the ashing process, the reducing gas is a radical.

13. The method of stripping photoresist of claim 1, wherein a material of the contact structures comprises nickel silicide or an alloy containing nickel silicide.

14. The method of stripping photoresist of claim 13, wherein the alloy containing nickel silicide comprises platinum or palladium.

15. The method of stripping photoresist of claim 1, wherein a material of the barrier layer comprises silicon nitride.

16. The method of stripping photoresist of claim 1, wherein after the step of removing the photoresist layer by using the reducing gas, further comprising:
performing a wet clean process.

17. The method of stripping photoresist of claim 16, wherein a solvent adopted for the wet clean process comprises an ammonium hydroxide-hydrogen peroxide water (APM) solution, or a fluorine based solution.

18. The method of stripping photoresist of claim 17, wherein a ratio of ammonium hydroxide, hydrogen peroxide and water of the APM solution is 1:1:100.
